(19) United States
(12) Patent Application Publication
(10) Pub. No.: US 2006/0192078 A1
(43) Pub. Date: Aug. 31, 2006

(54) Apparatus and method for recognizing gestures and computer readable recording medium having embodied thereon computer program for executing the method

(75) Inventors: Gyunghye Yang, Seoul (KR); Jihye Chung, Seoul (KR)

Correspondence Address: STAAS & HALSEY LLP;JIM LIVINGSTON, SUITE 700, 1201 NEW YORK AVENUE, N.W., WASHINGTON, DC, 20005, US

(73) Assignee: SAMSUNG ELECTRONICS CO., LTD., Suwon-si (KR)

(21) Appl. No.: 11/294,556

(22) Filed: Dec. 6, 2005

(30) Foreign Application Priority Data
Feb. 15, 2005 (KR) 10-2005-0012426

(51) Int. Cl. H01L 27/00

(52) U.S. Cl. 250/208.1

(57) ABSTRACT

A method of recognizing one or more gestures, and an apparatus to perform the method, the method including detecting positions at which light is emitted from a light emitter; and recognizing the one or more gestures according to a trajectory of the detected positions to perform a function corresponding to the trajectory of the detected positions.

### CROSS-REFERENCE TO RELATED APPLICATIONS

This application claims the benefit of Korean Patent Application No. 10-2005-0012426, filed on Feb. 15, 2005, in the Korean Intellectual Property Office, the disclosure of which is incorporated herein by reference.

### BACKGROUND OF THE INVENTION

1. Field of the Invention

The present invention relates to gesture recognition, and, more particularly, to a method, and an apparatus to perform the method, of recognizing gestures by sensing predetermined light, detecting a position at which the predetermined light is emitted, calculating a trajectory of the position with respect to time, and automatically performing a function corresponding to the calculated trajectory, and a computer readable recording medium having embodied thereon a computer program to cause a processor to execute the method.

2. Description of the Related Art

A personal computer (PC) operator can conventionally use a PC only by stroking or clicking a keyboard, a mouse, or the like. Similarly, a mobile phone owner can use a mobile phone to make a phone call, send a text message, play a game, or listen to music conventionally only by pressing a keypad of the mobile phone.

That is, to input data to a PC or a mobile phone, a user should operate a separate device, such as a keyboard, a mouse, or a keypad, which may be bothersome and/or inconvenient.

### SUMMARY OF THE INVENTION

The present invention provides an apparatus to recognize gestures by sensing predetermined light, detect positions at which the predetermined light is emitted, calculate a trajectory of the positions with respect to time, and automatically perform a function corresponding to the calculated trajectory.

The present invention also provides a method of recognizing gestures by sensing predetermined light, detecting positions at which the predetermined light is emitted, calculating a trajectory of the positions with respect to time, and automatically performing a function corresponding to the calculated trajectory.

The present invention also provides at least one computer readable medium storing instructions that control at least one processor to perform a gesture recognition method comprising sensing predetermined light, detecting positions at which the predetermined light is emitted, calculating the trajectory of the positions with respect to time, and automatically performing a function corresponding to the calculated trajectory.

Additional aspects and/or advantages of the invention will be set forth in part in the description which follows and, in part, will be apparent from the description, or may be learned by practice of the invention.

According to an aspect of the present invention, there is provided an apparatus to recognize gestures, comprising: a sensing unit to sense light during a predetermined period of time and detect positions at which the light is emitted; and an information processing unit to emit the light, calculate a trajectory of the detected positions with respect to time, and perform a function corresponding to the calculated trajectory.

The information processing unit may comprise: a light emitting unit to emit the light; a trajectory calculating unit to calculate the trajectory of the detected positions with respect to time; and a function performing unit to perform the function corresponding to the calculated trajectory.

The information processing unit may further comprise: a function storing unit to store function information at an address corresponding to a predetermined trajectory with respect to time; and a function mapping unit to read the function information having the address corresponding to the calculated trajectory from the stored function information, wherein the function performing unit performs the function indicated in the read function information.

The calculated trajectory may be a gesture. The sensing unit may detect the positions of the light emitting unit relative to the sensing unit. The sensing unit may comprise a plurality of sensing elements spaced apart from one another to sense the positions at which the light is emitted.

The sensing unit may transmit information regarding the detected positions to the trajectory calculating unit and may instruct the trajectory calculating unit to calculate the trajectory of the detected positions. The light emitting unit and the function performing unit may be integrally formed with each other. The light emitting unit and the function performing unit may be connected by a network.

The sensing unit, the light emitting unit, the trajectory calculating unit, the function performing unit, or a combination thereof may be attached to a user's body and be displaced by a motion of the user's body.

The sensing unit may be attached to a body part that performs a relatively small motion in relation to the body. The sensing unit may be attached to a headphone, an earphone, a necklace, or an earring mounted on the body. The light emitting unit, the trajectory calculating unit, the function performing unit, or a combination thereof may be attached to a body part that performs a relatively large motion in relation to the body.

The function performing unit may perform video reproduction, audio reproduction, or a combination thereof. The sensing unit may continuously detect the positions. The light may be an infrared ray or an ultrasonic wave.

According to another aspect of the present invention, there is provided a method of recognizing gestures, the method comprising: emitting light from a light emitter; sensing the light during a predetermined period of time and detecting positions at which the light is emitted; calculating a trajectory of the detected positions with respect to time; and performing a function corresponding to the calculated trajectory.

The detecting of the positions may comprise detecting the positions at which the light is emitted relative to a point at which the light is sensed.

The performing of the function may comprise: reading function information having an address corresponding to the calculated trajectory out of function information previously stored at the address, the address corresponding to a predetermined trajectory with respect to time; and performing the function indicated in the read function information.

According to another aspect of the present invention, there is provided at least one computer readable medium storing instructions that control at least one processor to perform a method of encoding image data, the method comprising: emitting light from a light emitter; sensing the light during a predetermined period of time and detecting positions at which the light is emitted; calculating a trajectory of the detected positions with respect to time; and performing a function corresponding to the calculated trajectory.

According to another aspect of the present invention, there is provided an apparatus to recognize one or more gestures, comprising: a sensing unit to detect positions at which a light is emitted; and a gesture recognizing unit to recognize the one or more gestures according to a trajectory of the detected positions.

According to another aspect of the present invention, there is provided a method of recognizing one or more gestures, the method comprising: detecting positions at which light is emitted from a light emitter; and recognizing the one or more gestures according to a trajectory of the detected positions.

### BRIEF DESCRIPTION OF THE DRAWINGS

These and/or other aspects and advantages of the invention will become apparent and more readily appreciated from the following description of the embodiments, taken in conjunction with the accompanying drawings of which:

FIG. 1 is a block diagram illustrating an apparatus to recognize gestures according to an embodiment of the present invention;

FIGS. 2 through 4D are reference diagrams illustrating the principle of gesture recognition according to embodiments of the present invention; and

FIG. 5 is a flow chart illustrating a method of recognizing gestures according to an embodiment of the present invention.

### DETAILED DESCRIPTION OF THE PREFERRED EMBODIMENTS

Reference will now be made in detail to the embodiments of the present invention, examples of which are illustrated in the accompanying drawings, wherein like reference numerals refer to the like elements throughout. The embodiments are described below to explain the present invention by referring to the figures.

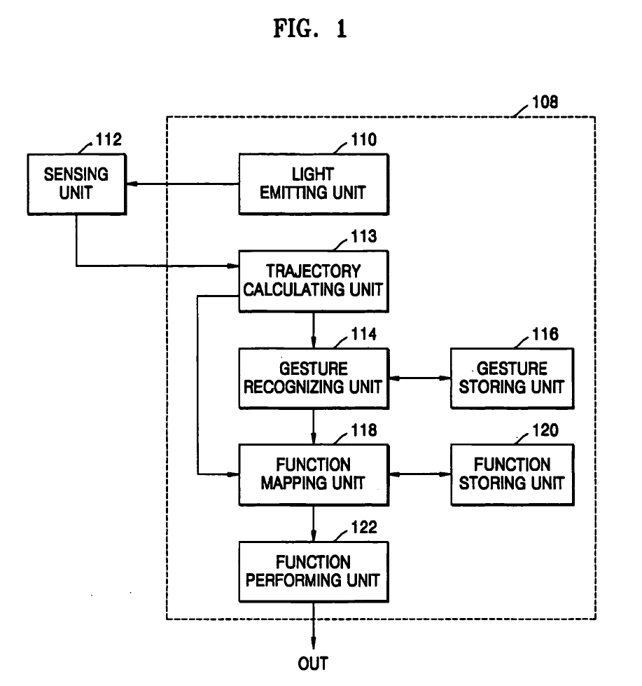

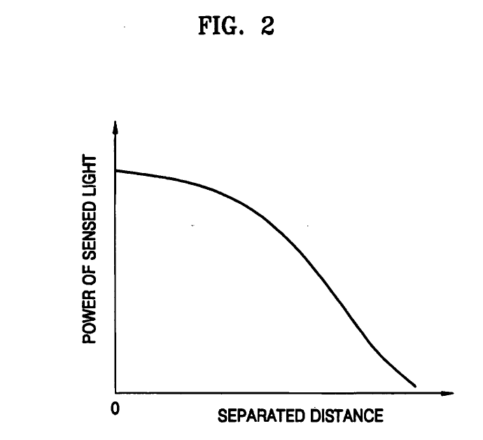

FIG. 1 is a block diagram illustrating an apparatus to recognize gestures (referred to as the apparatus hereinafter) according to an embodiment of the present invention. The apparatus includes an information processing unit 108 and a sensing unit 112. Here, the information processing unit 108 includes a light emitting unit 110, a trajectory calculating unit 113, a gesture recognizing unit 114, a gesture storing unit 116, a function mapping unit 118, a function storing unit 120, and a function performing unit 122. FIGS. 2 through 4 are reference diagrams illustrating the principle of gesture recognition according to an embodiment of the present invention.

The sensing unit 112 senses light for a predetermined period of time and detects a position at which the light is emitted. The information processing unit 108 emits the light, calculates the trajectory of the position detected by the sensing unit 112 with respect to time, and performs a function corresponding to the calculated trajectory. Here, the position may be a three-dimensional position.

The light emitting unit 110 emits the light. The light may have a preset frequency, and is preferably, though not necessarily, an infrared ray or an ultrasonic wave. Infrared light is very adept for this embodiment since it has a wide bandwidth and a high transmission speed, and permission is not needed to use infrared light.

The sensing unit 112 senses the light. To this end, the sensing unit 112 may include a light receiving unit (not shown). The sensing unit 112 may sense the emitted light out of various lights incident thereon, thereby differentiating between the emitted light and the other various lights.

Accordingly, the light emitting unit 110 may emit light, and the sensing unit 112 may sense the emitted light for the specified period of time and detect the position of the light emitting position 110. Since the sensing unit 112 senses the light emitted from the light emitting unit 110 for the specified period of time, the sensing unit 112 detects the position of the light emitting unit 110 for the predetermined period of time. The sensing unit 112 transmits information regarding the detected position to the trajectory calculating unit 113, and instructs the trajectory calculating unit 113 to perform its function.

Since the sensing unit 112 senses the light, the sensing unit 112 can determine a distance between the light emitting unit 110 and the sensing unit 112. That is, the sensing unit 112 can determine the distance between the light emitting unit 110 and the sensing unit 112 by comparing the power of the light sensed to the power of light emitted from the light emitting unit 110. Here, the sensing unit 112 may recognize information on the power of the light previously emitted from the light emitting unit 110.

In this way, the sensing unit 112 can detect the power of the light right after it is emitted from the light emitting unit 110, and the relative power of the sensed light. If the light emitting unit 110 emits light with a constant power, the sensing unit 112 can simultaneously detect the light emitted from the light emitting unit 110 and the relative power of the light sensed. Although the sensing unit 112 can instruct the light emitting unit 110 to emit light and sense the emitted light, it is preferable, though not necessary, that the sensing unit 112 detect the position of the light emitting unit 110 by sensing the emitted light without previous information regarding the position of the light emitting unit 110. To this end, as described above, the frequency of the light emitted from the light emitting unit 110 and the frequency of the light sensed by the sensing unit 112 may be equal to each other and previously set.

FIG. 2 is a graph illustrating a relationship between a separated distance and power of sensed light. Here, the separated distance denotes a distance between the light emitting unit 110 and the sensing unit 112, and may be a straight line. Further, the power of sensed light denotes the power of light sensed by the sensing unit 112, and may be the relative power of the light.

Referring to the graph of FIG. 2, as the separated distance increases, the power of the sensed light decreases. Accordingly, the sensing unit 112 can detect the distance between the light emitting unit 110 and the sensing unit 112 using the power of the sensed light. That is, the sensing unit 112 can sense the separated distance by sensing light given by the light emitting unit 110. The power of the sensed light and the separated distance can be expressed as the following:
D=K+1/P (1)
wherein D denotes the separated distance, P denotes the power of the sensed light, and K denotes a constant.

Such a distance recognition method is disclosed in the paper “Receiver Angle Diversity Design for High-Speed Diffuse Indoor Wireless Communications” by Khoo, SOO H., Zhang, Wenwei, Faulkner, Grahame E., O'Brien, Dominic C, and Edwards, David J., P. 116 to 124, Vol. 4530, SPIE (The International Society for Optical Engineering), Optical Wireless Communications IV, November, 2001.

In the meanwhile, the sensing unit 112 can detect a direction in which the light emitting unit 110 is disposed by sensing the emitted light. To this end, the sensing unit 112 may include one or more sensing elements (not shown) which can determine the position of the light emitting unit 110 by sensing light emitted from the light emitting unit 110 for a predetermined period of time. It is preferable, though not necessary, that the sensing unit 112 include a plurality of sensing elements that are spaced apart from one another. Accordingly, the sensing unit 112 can accurately determine the direction in which the light emitting unit 110 is positioned on the basis of the light receiving unit (not shown) of the sensing unit 112.

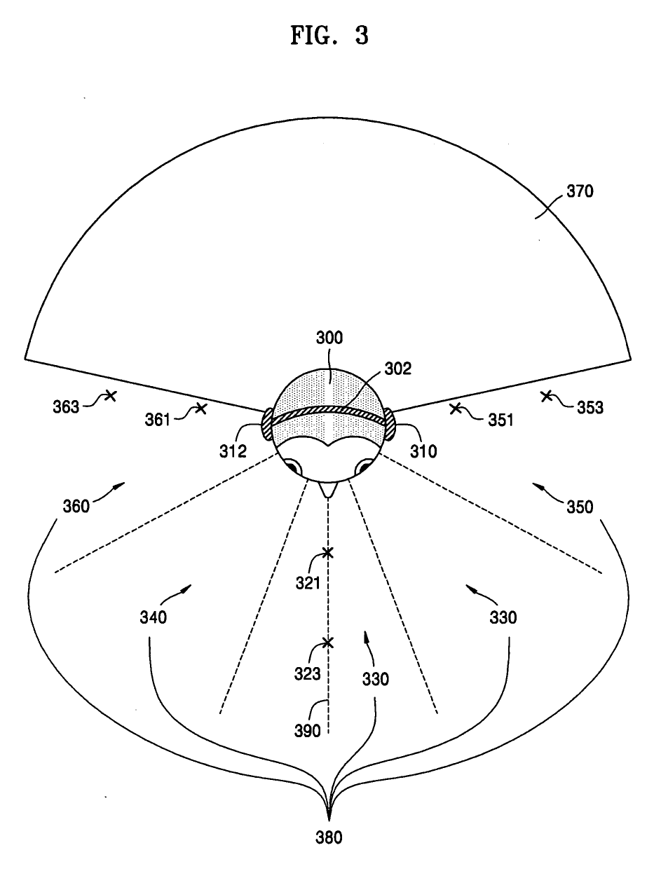

As described above, when the sensing unit 112 includes a plurality of sensing elements, the sensing elements may be spaced from one another. FIG. 3 is a diagram illustrating an area over which light sensed by the sensing unit 112 may be distributed. Referring to FIG. 3, the sensing unit 112 is made up of two sensing elements (not shown).

Reference numeral 300 designates a body part that performs a relatively small motion. That is, reference numeral 300 designates a body part that does not have a great degree of movement, such as, for example, the head and the neck. Reference numeral 302 designates an object (referred to as a fixed object) attached to the body part 300, and which includes the sensing unit 112. For example, the fixed object 302 may include a headphone, an earphone, an earring, a necklace, or the like.

In this embodiment of the present invention, reference numeral 300 designates the top of a user's head, and reference numeral 302 designates a headphone mounted on the user's head. This is for the convenience of explanation, and the present invention is not limited thereto.

The sensing unit 112 may be attached to the body such that the sensing unit 112 is displaced by the motion of the body. Specifically, the sensing unit 112 may be attached to a body part that performs a relatively small motion.

The light emitting unit 110 may be attached to the body such that the light emitting unit 110 is displaced by the motion of the body. Specifically, the light emitting unit 110 may be attached to a body part that performs a relatively large motion, such as, for example, the hand or the foot.

The light emitting unit 110 may be attached to a predetermined movable object (referred to as a movable object hereinafter), and the movable object may be a portable object. For example, the light emitting unit 110 may be integrated into a movable object held in the hand. The movable object may include a mobile phone, an MP3 player, a CD player, a portable multimedia player (PMP), etc.

Referring to FIG. 3, the headphone 302 includes cover units 310 and 312 respectively covering both ears. The left cover unit 310 covers the left ear, and the right cover unit 312 covers the right ear, and the cover units 310 and 312 respectively have sensing elements (not shown). Here, the light emitting unit 110 is included in a mobile phone (not shown) held in the user's hand, and the sensing unit 112 is included in the headphone 302.

Reference numeral 370 designates an area (referred to as a unrecognizable area hereinafter) over which light may be distributed that is not sensed by the sensing unit 112, and reference numeral 380 designates an area (referred to as a recognizable area hereinafter) over which light may be distributed that is sensed by the sensing unit 112. The area 380 may be divided into five areas 320, 330, 340, 350, and 360. Here, the five areas are merely suggested as categorized for convenience of explanation, and thus the present invention is not limited thereto.

The unrecognizable area 370 is an area in which the mobile phone, held in the hand of the user, cannot be positioned. The area 320 is disposed on the front side relative to the face of the user, and the range of the area 320 is approximately 10 degrees about a reference line 390. The area 330 is disposed on the center-left side of the user's face, and the range of the area 330 is about 10 to 45 degrees on the user's left side from the reference line 390.

Similarly, the area 340 is disposed on the center-right side of the face of the user, and the range of the area 340 is about 10 to 45 degrees on the user's right side from the reference line 390. Further, the area 350 is disposed on the left side of the user's face, and the range of the area 350 is about 45 to 60 degrees on the user's left side from the reference line 390. The area 360 is disposed on the right side of the user's face, and the range of the area 360 is about 45 to 60 degrees on the user's right side from the reference line 390.

If the light emitting unit 110 is present at a point 361 or 363, the sensing element of the left cover unit 310 cannot sense light emitted from the light emitting unit 110. This is expressed as the following:
P(Ri)=0 (2)
wherein Ri denotes the power of light sensed by the sensing element of the left cover unit 310.

Similarly, if the light emitting unit 110 is present at a point 351 or 353, the sensing element of the right cover unit 312 cannot sense light emitted from the sensing unit 112. This is expressed as the following:
P(Rr)=0 (3)
wherein Rr denotes the power of light sensed by the sensing element of the right cover unit 312.

If the light emitting unit 110 is present at a point 321 or 323, the value of P(Ri) and the value of P(Rr) become equal to each other.

As a result, the direction in which the light emitting unit 110 is positioned relative to the sensing unit 112 is expressed as the following:
O=f(P(Rr)/P(Ri)) (4)
wherein O denotes an orientation and f denotes a function. Accordingly, the direction in which the light emitting unit 110 is positioned based on the sensing unit 112 may be determined according to the ratio of P(Rr) to P(Ri). Accordingly, O can also be expressed as the following:
O=f(P(Ri)/P(Rr)) (5).

Consequently, the sensing unit 112 senses the direction in which the light emitting unit 110 is positioned relative to the sensing unit 112. That is, the sensing unit 112 senses the distance between the light emitting unit 110 and the sensing unit 112, and the direction in which the light emitting unit 110 is positioned relative to the sensing unit 112.

The trajectory calculating unit 113 calculates the trajectory of the position of the light emitting unit 110 with respect to time indicated in position information transmitted from the sensing unit 112. Here, the trajectory with respect to time refers to the course of change of position of the light emitting unit 110 relative to the sensing unit 112 with respect to time.

Meanwhile, when the sensing unit 112 continuously detects the position of the light emitting unit 110 for a predetermined period of time, the calculated trajectory is a continuous trajectory. When the sensing unit 112 detects the position of the light emitting unit 110 discontinuously for a predetermined period of time, the calculated trajectory is a discontinuous trajectory. Here, the predetermined period of time may be set in advance and may vary.

Information regarding the trajectory calculated by the trajectory calculating unit 113 may be transmitted to the gesture recognizing unit 114 and/or the function mapping unit 118.

The gesture recognizing unit 114 receives the information regarding the calculated trajectory from the trajectory calculating unit 113, and recognizes a gesture corresponding to the calculated trajectory. To this end, the gesture recognizing unit 114 may read gesture information having an address corresponding to the calculated trajectory out of the gesture storing unit 116. Accordingly, the gesture recognizing unit 114 can recognize a gesture indicated by the trajectory of the detected position.

The gesture storing unit 116 stores predetermined gesture information at addresses which respectively correspond to a predetermined trajectory with respect to time. Thus, the gesture information is data stored in the gesture storing unit 116, and the trajectory corresponds to an address of the data in the gesture storing unit 116. Here, gesture information signifies information regarding a gesture that is previously embodied and set.

That is, the gesture recognizing unit 114 recognizes whether the calculated trajectory indicates a gesture such as a greeting gesture, a sketching gesture, or other such gestures. However, since the gesture is no more than the calculated time-based trajectory, the gesture recognizing unit 114 and the gesture storing unit 116 may not be included in the apparatus.

The gesture recognizing unit 114 transmits the recognized gesture information to the function mapping unit 118, and instructs the function mapping unit 118 to perform the function mapping. If the gesture recognizing unit 114 and the gesture storing unit 116 are not included in the apparatus, the function mapping unit 118 may receive instructions from the trajectory calculating unit 113. Herein, the trajectory calculating unit 113 transmits the information regarding the calculated trajectory to the function mapping unit 118.

If the function mapping unit 118 receives instructions from the gesture recognizing unit 114, the function mapping unit 118 reads function information, corresponding to the received gesture information, from the function storing unit 120. In this case, the function storing unit 120 stores predetermined function information in an address, which corresponds to predetermined gesture information. Therefore, the function information is data stored in the function storing unit 120, and the gesture information corresponds to an address of the data in the function storing unit 120.

However, if the function mapping unit 118 receives instructions from the trajectory calculating unit 113, the function mapping unit 118 reads function information corresponding to the received trajectory from the function storing unit 120. In this case, the function storing unit 120 stores predetermined function information in an address which corresponds to a predetermined trajectory. Here, the function information is data stored in the function storing unit 120, and the trajectory corresponds to an address of the data in the function storing unit 120.

Here, the function storing unit 120 can store predetermined function information in an address which corresponds to a predetermined trajectory, or can store predetermined function information in an address, which corresponds to predetermined gesture information. Here, the function information indicates a function performable by the function performing unit 122, which will be explained below.

The function performing unit 122 performs the function indicated in the function information read by the function mapping unit 118. Accordingly, the function performing unit 122 performs the function corresponding to the trajectory calculated by the trajectory calculating unit 113. OUT denotes a function performed by the function performing unit 122. The function performing unit 122 may perform at least one of video reproduction and audio reproduction.

As described above, the information processing unit 108 may be included in the movable object, and the sensing unit 112 may be included in the fixed object. The fixed object may be attached to a body part with relatively small motion, and the movable object may be attached to a body part with relatively large motion. The fixed object may include items such as a headphone, an earphone, an earring, a necklace, etc., and the movable object may include items such as a PDP, a mobile phone, an MP3 player, and the like. Since the type of the fixed object is not limited, the sensing unit 112 being included in the fixed object is not a limiting factor in its practical applications.

If the movable object is a mobile phone, the function performing unit 122 may perform various functions such as, for example, to make a phone call, send a message, listen to an MP3, and play a game.

The light emitting unit 110 and the function performing unit 122 may be integrally formed with each other. That is, for example, when the movable object is a mobile phone, the light emitting unit 110 may also be included in the mobile phone. However, the present invention is not limited thereto, and the light emitting unit 110 and the function performing unit 122 may be connected in a manner such as, for example, by a network.

For example, the light emitting unit 110 only may be attached to the hand, and the function performing unit 122, which performs a function corresponding to the time-based trajectory calculated according to the motion of the hand detected by the sensing unit 112, may be put at a point distanced from the body. In this case, the function performing unit 122 and the light emitting unit 110 may be connected by a network to communicate with each other.

In the meantime, the trajectory calculating unit 113, the gesture recognizing unit 114, the gesture storing unit 116, the function mapping unit 118, and the function storing unit 120 may be integrally formed with the function performing unit 122, but the present invention is not limited thereto.

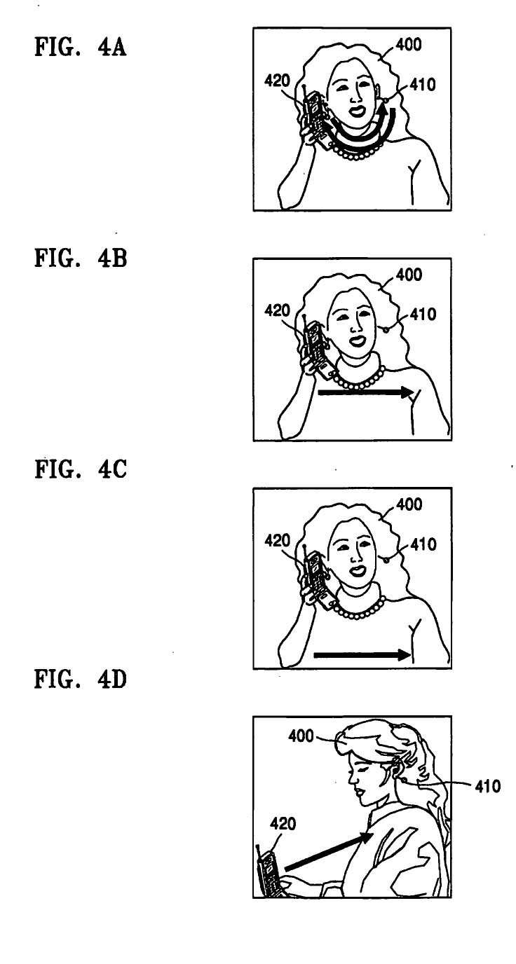

FIGS. 4A-4D illustrate examples of various gestures. It is assumed in these embodiments that the light emitting unit 110 and the function performing unit 122 are included in a mobile phone 420 held in the hand of a user 400, and the sensing unit 112 is included in an earring 410 worn by the user 400. If a gesture as shown in FIG. 4A is matched with a function of the function storing unit 120 in which the mobile phone 420 is automatically dialled to a fifth telephone number of a telephone number list stored therein, the mobile phone 420 is automatically dialled to the fifth telephone number without the operation of a keypad by the user 400.

Similarly, if a gesture as shown in FIG. 4B is matched with a text messaging function of the function storing unit 120, the mobile phone 420 automatically performs the text messaging function without keypad operation.

If a gesture as shown in FIG. 4C is matched with an MP3 listening function of the function storing unit 120, the mobile phone 420 automatically performs MP3 reproduction without keypad operation.

If a gesture as shown in FIG. 4D is matched with a game function of the function storing unit 120, the mobile phone 420 automatically performs a game function without keypad operation.

Although four examples are shown in FIGS. 4A-4D, these examples are merely shown for convenience of explanation, and the present invention is not limited thereto.

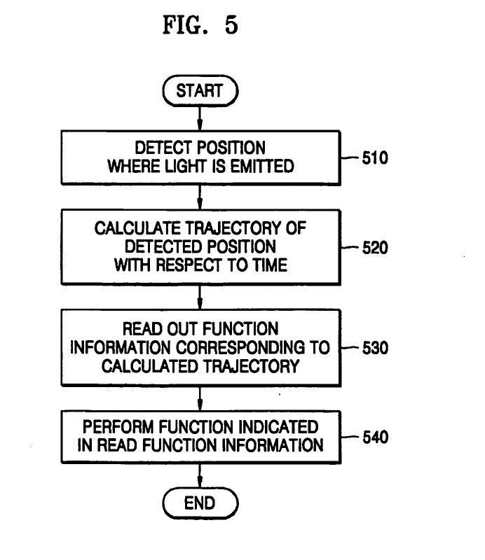

FIG. 5 is a flow chart illustrating a method of recognizing gestures according to an embodiment of the present invention. The method includes detecting a position and calculating a trajectory in operations 510 and 520, reading function information in operation 530, and performing a function corresponding to the read function information in operation 540.

In operation 510, the sensing unit 112 senses light for a predetermined period of time and detects a position where the light is emitted. That is, the sensing unit 112 detects the position of the light emitting unit 110 for the predetermined period of time. In operation 520, the trajectory calculating unit 113 calculates the trajectory of the detected position with respect to time. In operation 530, the function mapping unit 118 reads function information corresponding to the calculated trajectory from the function storing unit 120.

In operation 540, the function performing unit 122 automatically performs the function corresponding to the read function information.

In addition to the above-described embodiments, the method of the present invention can also be implemented by executing computer readable code/instructions in/on a medium, e.g., a computer readable medium. The medium can correspond to any medium/media permitting the storing and/or transmission of the computer readable code. The code/instructions may form a computer program.

The computer readable code/instructions can be recorded/transferred on a medium in a variety of ways, with examples of the medium including magnetic storage media (e.g., ROM, floppy disks, hard disks, etc.), optical recording media (e.g., CD-ROMs, or DVDs), and storage/transmission media such as carrier waves, as well as through the Internet, for example. The medium may also be a distributed network, so that the computer readable code/instructions is stored/transferred and executed in a distributed fashion. The computer readable code/instructions may be executed by one or more processors.

As described above, the method of recognizing gestures, the computer readable medium having embodied thereon instructions to perform the method, and the apparatus to perform the method can recognize a user's gesture.

Also, the gesture recognition apparatus and method and the computer readable recording medium can recognize various types of gestures.

Moreover, the gesture recognition apparatus and method and the computer readable recording medium can recognize the user's gesture made without difficulty, and can allow a predetermined device to automatically perform a function corresponding to the recognized gesture among its available functions.

Although a few embodiments of the present invention have been shown and described, it would be appreciated by those skilled in the art that changes may be made in these embodiments without departing from the principles and spirit of the invention, the scope of which is defined in the claims and their equivalents.

What is claimed is:

1. An apparatus to recognize gestures, comprising:
a sensing unit to sense light during a predetermined period of time and detect positions at which the light is emitted; and
an information processing unit to emit the light, calculate a trajectory of the detected positions with respect to time, and perform a function corresponding to the calculated trajectory.

2. The apparatus of claim 1, wherein the information processing unit comprises:
a light emitting unit to emit the light;
a trajectory calculating unit to calculate the trajectory of the detected positions with respect to time; and
a function performing unit to perform the function corresponding to the calculated trajectory.

3. The apparatus of claim 2, wherein the information processing unit further comprises:
a function storing unit to store function information at an address corresponding to a predetermined trajectory with respect to time; and
a function mapping unit to read the function information having the address corresponding to the calculated trajectory from the stored function information,
wherein the function performing unit performs the function indicated in the read function information.

4. The apparatus of claim 1, wherein the calculated trajectory is a gesture.

5. The apparatus of claim 2, wherein the sensing unit detects the positions of the light emitting unit relative to the sensing unit.

6. The apparatus of claim 1, wherein the sensing unit comprises a plurality of sensing elements spaced apart from one another to sense the positions at which the light is emitted.

7. The apparatus of claim 2, wherein the sensing unit transmits information regarding the detected positions to the trajectory calculating unit and instructs the trajectory calculating unit to calculate the trajectory of the detected positions.

8. The apparatus of claim 2, wherein the light emitting unit and the function performing unit are integrally formed with each other.

9. The apparatus of claim 2, wherein the light emitting unit and the function performing unit are connected by a network.

10. The apparatus of claim 2, wherein the sensing unit, the light emitting unit, the trajectory calculating unit, the function performing unit, or a combination thereof is attached to a user's body and is displaced by a motion of the user's body.

11. The apparatus of claim 10, wherein the sensing unit is attached to a body part that performs a relatively small motion in relation to the body.

12. The apparatus of claim 11, wherein the sensing unit is attached to a headphone, an earphone, a necklace, or an earring mounted on the body.

13. The apparatus of claim 10, wherein the light emitting unit, the trajectory calculating unit, the function performing unit, or a combination thereof is attached to a body part that performs a relatively large motion in relation to the body.

14. The apparatus of claim 2, wherein the function performing unit performs video reproduction, audio reproduction, or a combination thereof.

15. The apparatus of claim 1, wherein the sensing unit continuously detects the positions.

16. The apparatus of claim 1, wherein the light is an infrared ray or an ultrasonic wave.

17. A method of recognizing gestures, the method comprising:
emitting light from a light emitter;
sensing the light during a predetermined period of time and detecting positions at which the light is emitted;
calculating a trajectory of the detected positions with respect to time; and
performing a function corresponding to the calculated trajectory.

18. The method of claim 17, wherein the detecting of the positions comprises detecting the positions at which the light is emitted relative to a point at which the light is sensed.

19. The method of claim 17, wherein the performing of the function comprises:
reading function information having an address corresponding to the calculated trajectory out of function information previously stored at the address, the address corresponding to a predetermined trajectory with respect to time; and
performing the function indicated in the read function information.

20. At least one computer readable medium storing instructions that control at least one processor to perform a method of encoding image data, the method comprising:
emitting light from a light emitter;
sensing the light during a predetermined period of time and detecting positions at which the light is emitted;
calculating a trajectory of the detected positions with respect to time; and
performing a function corresponding to the calculated trajectory.

21. An apparatus to recognize one or more gestures, comprising:
a sensing unit to detect positions at which a light is emitted; and
a gesture recognizing unit to recognize the one or more gestures according to a trajectory of the detected positions.

22. The apparatus of claim 21, further comprising a light emitting unit to emit the light.

23. The apparatus of claim 21, further comprising a function performing unit to perform a function corresponding to the trajectory of the detected positions.

24. The apparatus of claim 23, further comprising a function storage unit to store function information corresponding to the trajectory of the detected positions, wherein the function performing unit performs the function indicated by the function information read from the function storage unit.

25. The apparatus of claim 21, wherein the sensing unit comprises a plurality of sensing elements spaced apart from one another to sense the positions at which the light is emitted.

26. The apparatus of claim 25, wherein the positions are detected in three-dimensional space.

27. A method of recognizing one or more gestures, the method comprising:
detecting positions at which light is emitted from a light emitter; and
recognizing the one or more gestures according to a trajectory of the detected positions.

28. The method of claim 27, further comprising performing a function corresponding to the trajectory of the detected positions.

29. The method of claim 28, wherein the performing the function comprises reading function information corresponding to the trajectory from a function storage unit, and performing the function indicated by the read function information.

30. The method of claim 27, wherein the detecting the positions at which the light is emitted comprises sensing the light by a light sensing unit.

31. The method of claim 30, wherein the light sensing unit comprises a plurality of sensing elements spaced apart from one another to sense the positions at which the light is emitted.

32. The method of claim 31, wherein the positions are detected in three-dimensional space.
